(19) United States
(12) Patent Application Publication
(10) Pub. No.: US 2026/0190937 A1
(43) Pub. Date: Jul. 2, 2026

(54) SUBSTRATE TRANSFER APPARATUS AND SUBSTRATE PROCESSING APPARATUS

(71) Applicant: SEMES CO., LTD., Cheonan-si (KR)

(72) Inventors: Sang Hyun SON, Busan (KR); Young Sik BANG, Yongin-si (KR); Yong Jun SEO, Hwaseong-si (KR); Sang Min HA, Hwaseong-si (KR); Ik Ho LEE, Suwon-si (KR); Dong Joo SHIN, Suwon-si (KR)

(73) Assignee: SEMES CO., LTD., Cheonan-si (KR)

(21) Appl. No.: 19/436,458

(22) Filed: Dec. 30, 2025

(30) Foreign Application Priority Data
Dec. 30, 2024 (KR) 10-2024-0200467

(51) Int. Cl. H10P 72/50; H10P 72/00; H10P 72/30

(52) U.S. Cl. CPC H10P 72/53; H10P 72/0606; H10P 72/3302

(57) ABSTRACT

A substrate transferring apparatus and a substrate processing apparatus are provided. The substrate transferring apparatus includes a base, a hand mounted on the base to support a substrate, and a position detector for detecting a position of the substrate. The position detector includes at least one sensor unit disposed at a position corresponding to a peripheral portion of the substrate. Each sensor unit includes a light emitting unit and a light receiving unit facing each other. The light receiving unit includes a plurality of light receiving members, wherein a gap between the light receiving members is greater than a width of a notch formed on the substrate. This configuration enables efficient identification of the notch and alignment of the substrate by comparing light amount data received by the light receiving members.

### CROSS-REFERENCE TO RELATED APPLICATION

This application claims priority to and the benefit of Korean Patent Application No. 10-2024-0200467 filed in the Korean Intellectual Property Office on Dec. 30, 2024, the entire contents of which are incorporated herein by reference.

### TECHNICAL FIELD

The present invention relates to a substrate transferring apparatus and a substrate processing apparatus, and more particularly, to a substrate transferring apparatus and a substrate processing apparatus that transfer a substrate by a hand.

### BACKGROUND ART

In order to manufacture a semiconductor device or a flat panel display, various processes, such as a deposition process, a photolithography process, an etching process, and a cleaning process, are performed. Among the processes, the photolithography process includes a coating process of forming a film by applying a photosensitive liquid, such as a photoresist, on a surface of the substrate, an exposure process of transferring a circuit pattern to the film formed on the substrate, and a developing process of selectively removing the film formed on the substrate in an exposed region or a region opposite to the region. In addition, before and after these coating process, exposure process, and development process are performed, a heat treatment process is performed.

These processes are performed in a plurality of chambers, respectively. To this end, the substrate needs to be transferred from one chamber to another, and the transferring of the substrate is made by a transfer robot. The transfer robot is designed to stably transfer the substrate within a complex processing apparatus structure, and a precision device, such as a robot arm, is used to accurately dispose the substrate at an inlet or work area of each chamber. The transfer robot automatically transfers the substrate based on a preset path and location information, and is designed to be suitable for a working environment with high speed and precision. However, during the transfer process, there is a possibility that the position of the substrate may be deviated due to external vibration, mechanical wear of the processing apparatus, or a minute error in the set value. This position error may affect the process result.

To solve the position error, a system that measures and corrects a wafer center position is used. In general, for measuring the center of the wafer, a single-point proximity sensor, a line CCD sensor (one-dimensional), a CMOS sensor (two-dimensional), a trilateration method using three or more line Charge-Coupled Device (CCD) sensors and Complementary Metal-Oxide Semiconductor (CMOS) sensors, and the like are used..

When a single-point proximity sensor is used, it is impossible to accurately measure the degree of deviation in a two-dimensional position, the degree of deviation can only be measured while moving, and there is a problem that the precision varies depending on the moving speed. When a line CCD sensor is used, there is a problem that two-dimensional data can be processed when using a CMOS sensor, but the data collection and processing time is long, and there is a possibility of error due to the notch of the wafer.

The wafer position can be calculated by applying the trilateration method using three or more line CCD and CMOS sensors, but additional error factors occur because the wafer is not completely circular and due to the presence of the notch. To solve the notch problem, a method of adding sensors or aligning the notch so that the notch is not included in the measurement area is needed.

In particular, when a CCD-based trilateration method, at least four sensors are required to search for the notch point. Increasing the number of sensors may reduce errors, but greatly affects the performance of the light source in CCDs with pixel intervals in micrometers. The additional installation of the light source and the sensor device causes space and wiring problems, thereby increasing the cost of equipment and wiring. In addition, there is a problem that a design that minimizes these factors is required because the cost of installing an additional light source is high compared to the cost of a signal processing device.

### SUMMARY OF THE INVENTION

The present invention has been made in an effort to provide a substrate transferring apparatus and a substrate processing apparatus capable of efficiently processing a substrate.

The present invention has also been made in an effort to provide a substrate transferring apparatus and a substrate processing apparatus capable of improving substrate transfer efficiency.

The present invention has also been made in an effort to provide a substrate transferring apparatus and a substrate processing apparatus capable of searching for a notch point using three light sources.

The objectives of the present disclosure are not limited thereto and other objectives not stated herein may be clearly understood by those skilled in the art from the following description.

[symbol]

An exemplary embodiment of the present disclosure, an apparatus for transferring a substrate, the apparatus comprising: a base; a hand mounted on the base to support the substrate; a nd position detector for detecting a position of the substrate supported by the hand, wherein the position detector includes: at least one sensor unit provided at each position corresponding to at least one peripheral portion of the substrate to detect the at least one peripheral portion of the substrate, the at least one sensor unit includes: a light emitting unit installed on any one of the base and the hand to emit light; and a light receiving unit installed on the other of the base and the hand to receive the light emitted by the light emitting unit, the light receiving unit includes a plurality of light receiving members, and a gap between the plurality of light receiving members may be greater than a width of a notch formed on the substrate.

According to the exemplary embodiment of the present invention, wherein the plurality of light receiving members may be arranged in a circumferential direction based on a center of the substrate.

According to the exemplary embodiment of the present invention, wherein the width of the notch may be a width of an upper end of the notch.

According to the exemplary embodiment of the present invention, wherein the plurality of light receiving members may be provided as a plurality of light receiving sensors.

According to the exemplary embodiment of the present invention, wherein the light emitting unit may be provided as a light source to emit the light to the plurality of light receiving sensors.

According to the exemplary embodiment of the present invention, wherein the at least one sensor unit may be provided in plural to detect a plurality of peripheral portions of the substrate.

According to the exemplary embodiment of the present invention, further comprising: controller for controlling the hand and the position detector, wherein the controller receives data on the light from the plurality of light receiving sensors included in the plurality of sensor units, respectively, and obtains information on an amount of the light received by each of the plurality of light receiving sensors from the data on the light, and when there is one light receiving sensor of which the amount of light received is equal to or greater than an amount of light received by other light receiving sensors by a preset value or more among the plurality of light receiving sensors, the controller may determines that the notch is formed at a peripheral portion of the substrate corresponding to a position where the one light receiving sensor is provided.

According to the exemplary embodiment of the present invention, wherein the controller may calculates a center point of the substrate based on information on the amount of light received by each of the plurality of light receiving sensors, compares the center point of the substrate with a preset value to determine a degree of deviation of the substrate on the hand, and aligns a position of the substrate based on the degree of deviation.

According to the exemplary embodiment of the present invention, wherein the light emitting unit is installed above the base, and the light receiving unit may be installed under the hand.

An exemplary embodiment of the present disclosure, an apparatus for processing a substrate, the apparatus comprising: an index module including a load port and an index robot; and a treating module including a transfer chamber including a main transfer robot and a treating chamber placed on a side of the transfer chamber to process the substrate, wherein the main transfer robot includes: a base; a hand mounted on the base to support the substrate; and a position detector for detecting the position of the substrate supported by the hand, the position detector includes a plurality of sensor units provided at positions corresponding to three peripheral portions to detect the three peripheral portions of the substrate, each of the plurality of sensor units includes: a light emitting unit installed above the base to emit light; and a light receiving unit installed under the hand to receive the light emitted by the light emitting unit, and the light receiving unit may include a plurality of light receiving sensors.

According to the exemplary embodiment of the present invention, wherein each of the plurality of light receiving sensors receives the light emitted by the light emitting unit to may generate data on the light.

According to the exemplary embodiment of the present invention, wherein a gap between the plurality of light receiving sensors may be greater than a width of a notch formed on the substrate.

According to the exemplary embodiment of the present invention, wherein the plurality of light receiving sensors is disposed along a circumferential direction with respect to a center of the substrate, and the width of the notch may be a width of an upper end of the notch.

According to the exemplary embodiment of the present invention, wherein the light emitting unit may be provided as a light source to emit the light to each of the plurality of light receiving sensors.

According to the exemplary embodiment of the present invention, further comprising:
controller for controlling the hand and the position detector, wherein the controller receives data on the light from the plurality of light receiving sensors included in the plurality of sensor units, respectively, and obtains information on an amount of light received by each of the plurality of light receiving sensors from the data on the light, and when there is one light receiving sensor of which the amount of light received is equal to or greater than an amount of light received by other light receiving sensors by a preset value or more among the plurality of light receiving sensors, the controller may determines that the notch is formed at a peripheral portion of the substrate corresponding to a position where the one light receiving sensor is provided.

According to the exemplary embodiment of the present invention, wherein the controller may calculates a center point of the substrate based on information on the amount of light received by each of the plurality of light receiving sensors, compares the center point of the substrate with a preset value to determine a degree of deviation of the substrate on the hand, and aligns a position of the substrate based on the degree of deviation.

According to the exemplary embodiment of the present invention, wherein a size of the light emitting unit may be equal to or greater than a size of the light receiving unit.

An exemplary embodiment of the present disclosure, an apparatus for transferring a substrate, the apparatus comprising: a base; a hand mounted on the base to support a substrate; a position detector for detecting a position of the substrate supported by the hand; and a controller for controlling the hand and the position detector, the position detector includes at least one sensor unit provided at each position corresponding to at least one peripheral portion of the substrate to detect the at least one peripheral portion of the substrate, the at least one sensor unit includes: a light emitting unit installed above the base to emit light; and a light receiving unit installed under the hand to receive the light emitted by the light emitting unit, and the light receiving unit includes a plurality of light receiving sensors, and a gap between the plurality of light receiving sensors may be greater than a width of a notch formed on the substrate.

According to the exemplary embodiment of the present invention, wherein the plurality of light receiving sensors may be disposed along a circumferential direction with respect to a center of the substrate.

According to the exemplary embodiment of the present invention, wherein the width of the notch may be a width of an upper end of the notch.

According to the exemplary embodiment of the present invention, it is possible to efficiently process a substrate.

According to the exemplary embodiment of the present invention, it is possible to improve substrate transfer efficiency.

According to the exemplary embodiment of the present invention, it is possible to search for a notch point using three light sources.

According to the exemplary embodiment of the present invention, it is possible to reduce the cost by searching for the notch point using three light sources.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a perspective view schematically illustrating a substrate processing apparatus according to an exemplary embodiment of the present invention.

FIG. 2 is a front view of the substrate processing apparatus of FIG. 1.

FIG. 3 is a top plan view of a coating block in the substrate processing apparatus of FIG. 1.

FIG. 4 is a top plan view of a developing block in the substrate processing apparatus of FIG. 1.

FIG. 5 is a front view of a heat treating chamber of FIG. 3 or FIG. 4.

FIG. 6 is a front view of the heat treating chamber of FIG. 5.

FIG. 7 is a cross-sectional view schematically illustrating an example of the liquid treating chamber of FIG. 3 or FIG. 4.

FIG. 8 is a perspective view schematically illustrating a transfer robot of FIG. 3.

FIGS. 9 to 10 are diagrams for describing a light receiving unit according to the exemplary embodiment of the present invention.

FIGS. 11 to 12 are conceptual diagrams illustrating a notch detecting method according to an exemplary embodiment of the present invention.

FIG. 13 is a conceptual diagram for describing a substrate position aligning method according to the exemplary embodiment of the present invention.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as a target to be treated. However, the technical spirit of the present invention may be applied to apparatuses used for treating other types of substrates, other than wafers, as targets to be treated.

Hereinafter, an exemplary embodiment of the present invention will be described with reference to the accompanying drawings.

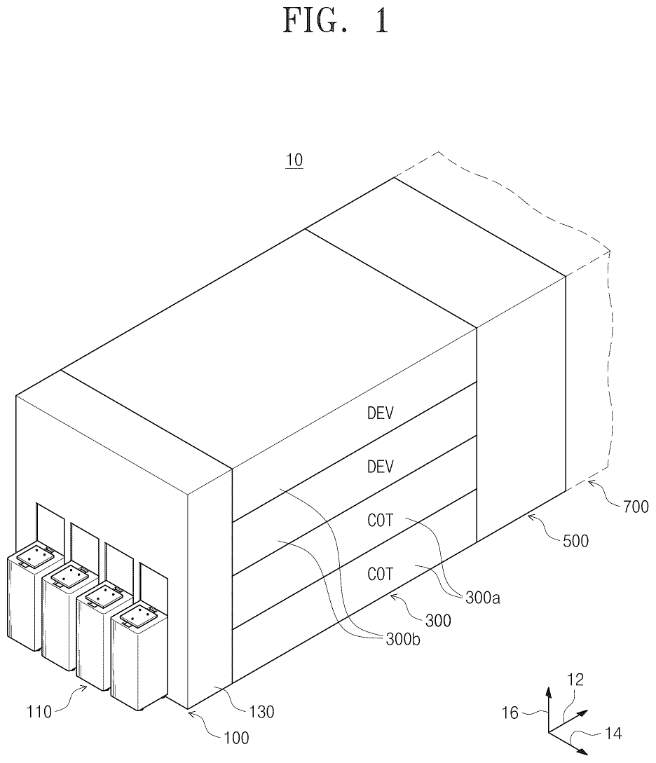

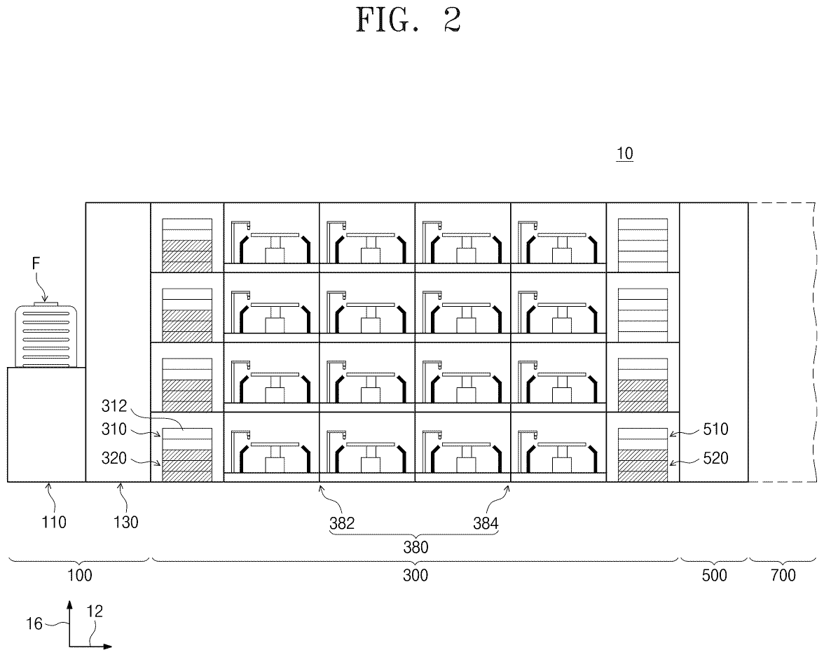

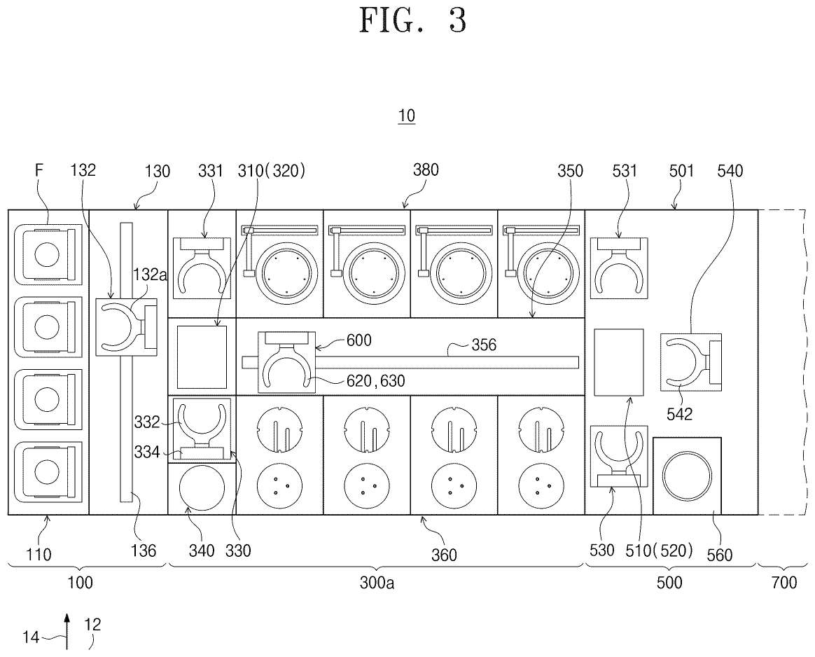

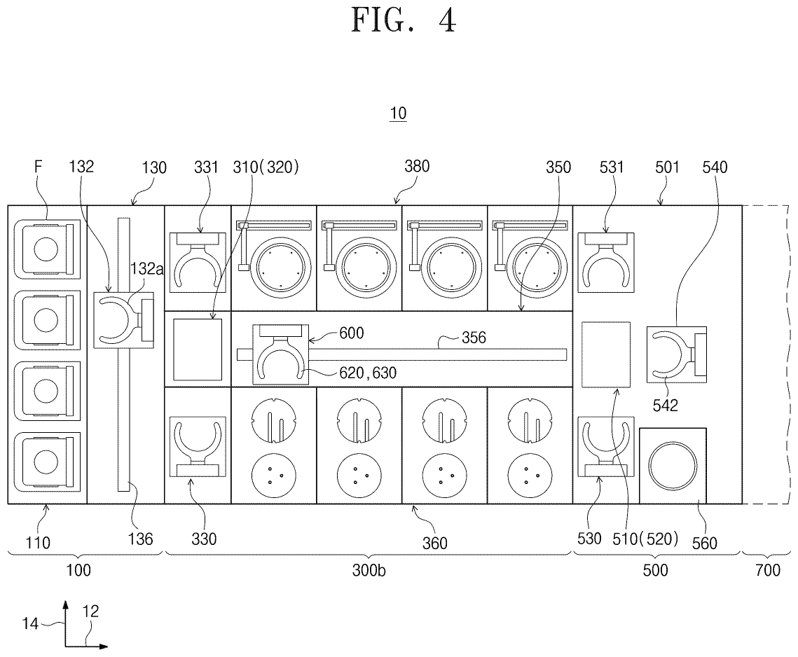

FIG. 1 is a perspective view schematically illustrating a substrate processing apparatus according to an exemplary embodiment of the present invention, and FIG. 2 is a front view of the substrate processing apparatus of FIG. 1. FIG. 3 is a top plan view of a coating block in the substrate processing apparatus of FIG. 1, and FIG. 4 is a top plan view of a developing block in the substrate processing apparatus of FIG. 1.

Referring to FIGS. 1 to 4, a substrate processing apparatus 10 includes an index module 100, a treating module 300, and an interface module 500. According to the exemplary embodiment, the index module 100, the treating module 300, and the interface module 500 are sequentially arranged in a line. Hereinafter, a direction in which the index module 100, the treating module 300, and the interface module 500 are disposed is referred to as a first direction 12, and when viewed from above, a direction perpendicular to the first direction 12 is referred to as a second direction 14, and a direction perpendicular to both the first direction 12 and the second direction 14 is referred to as a third direction 16.

The index module 100 is provided to transfer the substrate W between a container F in which the substrate W is accommodated and the treating module 300. A longitudinal direction of the index module 100 is provided in the second direction 14. The index module 100 includes a load port 110 and an index frame 130. The containers F in which the substrates W are accommodated are placed on the load ports 110. Based on the index frame 130, the load port 110 is located at a side opposite to the treating module 300. A plurality of load ports 110 may be provided, and the plurality of load ports 110 may be disposed in the second direction 14.

For example, as the container F, an airtight container F, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided to the index frame 130. A guide rail 136 is provided to the inside of the index frame 130. A longitudinal direction of the guide rail 136 is provided in the second direction 14. The index robot 132 is mounted on the guide rail 136 to be movable along the guide rail 136. The index robot 132 includes a hand 132a on which the substrate W is placed. The hand 132a may be provided may be provided to be capable of moving forward and backward, moving linearly along the third direction 16, and rotating and moving about the third direction 16 as an axis.

The treating module 300 may perform an application process and a development process on the substrate W. The treating module 300 includes a coating block 300a and a developing block 300b.

The coating block 300a performs a coating process on the substrate W before an exposure process is performed. The developing block 300b performs a development process on the substrate W after the exposure process is performed. A plurality of coating blocks 300a is provided. A plurality of coating blocks 300a may be provided to be stacked on each other. A plurality of developing blocks 300b may be provided. A plurality of developing blocks 300b may be provided to be stacked on each other. According to an example, two applying blocks 300a are provided, and two developing blocks 300b are provided. A plurality of applying blocks 300a may be positioned under the developing block 300b.

According to an example, the plurality of applying blocks 300a may be provided in the same structure. The films applied to the substrate W in each of the plurality of coating blocks 300a may be the same type of film. Optionally, depending on the coating block 300a, the films applied to the substrate W may be different types of films. The film applied to the substrate W includes a photoresist film. The film coated on the substrate W may further include an anti-reflection film. Optionally, the film coated on the substrate W may further include a protective film.

Furthermore, the two developing blocks 300b may be provided in the same structure. The developer supplied to the substrate W by the plurality of developing blocks 300b may be the same type of liquid. Optionally, the developer supplied to the substrate W according to the developing block 300b may be different types of developer. For example, when performing the process of removing the light-irradiated region of the register film on the substrate W, the developing process may be performed on one of the two developing blocks 300b, and when performing the process of removing the region not irradiated with light, the developing process may be performed on the other of the two developing blocks 300b.

Referring to FIG. 3, the applying block 300a includes a buffer unit 310, a cooling unit 320, a hydrophobization chamber 340, a transfer chamber 350, a heat treating chamber 360, and a liquid treating chamber 380.

The buffer unit 310, the cooling unit 320, and the hydrophobization chamber 340 are disposed adjacent to the index module 100. The hydrophobization chamber 340 and the buffer unit 310 may be sequentially disposed along the second direction 14. Also, the cooling unit 320 and the buffer unit 310 may be stacked in a vertical direction.

The buffer unit 310 includes one or a plurality of buffers 312. When a plurality of buffers 312 is provided, the plurality of buffers 312 may be disposed to be stacked therebetween. The buffer 312 provides a space in which the substrate W stays when the substrate W is transferred between the index module 100 and the treating module 300. The hydrophobization chamber 340 hydrophobizes the surface of the substrate W. The hydrophobization treatment may be performed before performing the application process on the substrate W. The hydrophobization treatment may be performed by supplying the hydrophobization gas to the substrate W while heating the substrate W. The cooling unit 320 cools the substrate W. The cooling unit 320 includes one or a plurality of cooling plates. When a plurality of cooling plates is provided, a plurality of cooling plates may be disposed to be stacked on each other. According to an example, the cooling unit 320 may be disposed below the buffer unit 310. A flow path through which cooling water flows may be formed in the cooling plate. The substrate W on which the hydrophobization treatment has been completed may be cooled in the cooling plate.

A transfer mechanism 330 is provided between the hydrophobization chamber 340 and the buffer unit 310 and between the hydrophobization chamber 340 and the cooling unit 320. The transfer mechanism 330 is provided to be able to transfer the substrate W between the buffer unit 310, the hydrophobization chamber 340, and the cooling unit 320.

The transfer mechanism 330 has a hand 332 on which the substrate W is placed, and the hand 332 may be provided to be capable of moving forward and backward, rotating about the third direction 16 as an axis, and moving along the third direction 16. According to an example, the transfer mechanism 330 is moved in the third direction 16 along the guide rail 334. The guide rail 334 extends from the applying block located at the bottommost end among the applying blocks 300a to the developing block located at the topmost end among the developing blocks 300b. Accordingly, the transfer mechanism 330 may transfer the substrate W between the blocks 300a and 300b provided on different layers. For example, the transfer mechanism 330 may transfer the substrate W between the applying blocks 300a positioned on different layers. In addition, the transfer mechanism 330 may transfer the substrate W between the applying block 300a and the developing block 300b.

Furthermore, another transfer unit 331 may be additionally provided at an opposite side to the side to which the hydrophobization chamber 340 is provided with respect to the buffer unit 310. Furthermore, the other transfer unit 331 may be provided to transfer the substrate W between the buffer unit 310 and the cooling unit 320 provided in different blocks 300a and 300b. Furthermore, the other transfer unit 331 may be provided to transfer the substrate W between the buffer unit 310 and the cooling unit 320 provided in different blocks 300a and 300b.

The transfer chamber 350 may be provided so that a longitudinal direction is parallel to the first direction 12. One end of the transfer chamber 350 may be located adjacent to the buffer unit 310 and/or the cooling unit 320. The other end of the transfer chamber 350 may be located adjacent to the interface module 500.

A plurality of heat treating chambers 360 is provided. Some of the heat treating chambers 360 are disposed along the first direction 12. Optionally, some of the liquid treating chambers 360 may be stacked along the third direction 16. All of the heat treating chambers 360 may be located on one side of the transfer chamber 350.

The liquid treating chamber 380 performs a liquid film forming process of forming a liquid film on the substrate W. According to an example, the liquid film forming process includes a resist film forming process. The liquid film forming process may include an antireflection film forming process. Optionally, the liquid film forming process may further include a protective film forming process. A plurality of liquid treating chambers 380 is provided. The liquid treating chambers 380 may be located on the side opposite to the heat treating chamber 360. For example, all liquid treating chambers 380 may be located on the other side of the transfer chamber 350. The liquid treating chambers 380 are arranged side by side along the first direction 12. Optionally, some of the liquid treating chambers 360 may be stacked along the third direction 16.

According to an example, the liquid treating chambers 380 include a front end liquid treating chamber 380a and a rear end liquid treating chamber 380b. The front end liquid treating chamber 380a is disposed relatively adjacent to the index module 100, and the rear end liquid treating chamber 380b is disposed more adjacent to the interface module 500.

The front end liquid treating chamber 380 applies a first liquid onto the substrate W, and the rear end liquid treating chamber 364 applies a second liquid onto the substrate W. The first liquid and the second liquid may be different types of liquids. According to an example, the first liquid may be a liquid for forming the antireflection film, and the second liquid may be a liquid for forming the photoresist film. The photoresist film may be formed on the substrate W on which the antireflection film is coated. Optionally, the first liquid may be a liquid for forming the photoresist film, and the second liquid may be a liquid for forming the antireflection film. In this case, the antireflection film may be formed on the substrate W on which the photoresist film is formed. Optionally, the first liquid and the second liquid may be the same type of liquid, and all of these may be liquids for forming a photoresist film.

Referring to FIG. 4, the developing block 300b includes a buffer unit 310, a cooling unit 320, a transfer chamber 350, a heat treating chamber 360, and a liquid treating chamber 380. The disposition of the buffer unit 310, the cooling unit 320, the transfer chamber 350, the heat treating chamber 360, and the liquid treating chamber 380 in the developing block 300b may be the same as the disposition of the buffer unit 310, the cooling unit 320, the transfer chamber 350, the heat treating chamber 360, and the liquid treating chamber 380 in the coating block 300a. When viewed from above, the buffer unit 310, the cooling unit 320, the transfer chamber 350, the heat treating chamber 360, and the liquid treating chamber 380 in the developing block 300b may be disposed at positions overlapping the positions of the buffer unit 310, the cooling unit 320, the transfer chamber 350, the heat treating chamber 360, and the liquid treating chamber 380 in the coating block 300a.

The heat treating chamber 360 performs a heating process on the substrate W. The heating process includes a post-exposure baking process performed on the substrate W on which the exposure process has been completed and a hard baking process performed on the substrate W on which the development process has been completed.

The liquid treating chamber performs a developing process of supplying a developer onto the substrate W and developing the substrate W.

In FIG. 3 or 4, a transfer robot 600 is provided in the transfer chamber 350. The transfer robot 600 transfers the substrate W between the buffer unit 310, the cooling unit 320, the heat treating chamber 360, the liquid treating chamber 380, and the buffer unit 510 or the cooling unit 520 of the interface module 500. A guide rail 356 whose longitudinal direction is provided parallel to the first direction 12 is provided in the transfer chamber 350, and the transfer robot 600 may be provided movable on the guide rail 356. The transfer robot 600 will be described later.

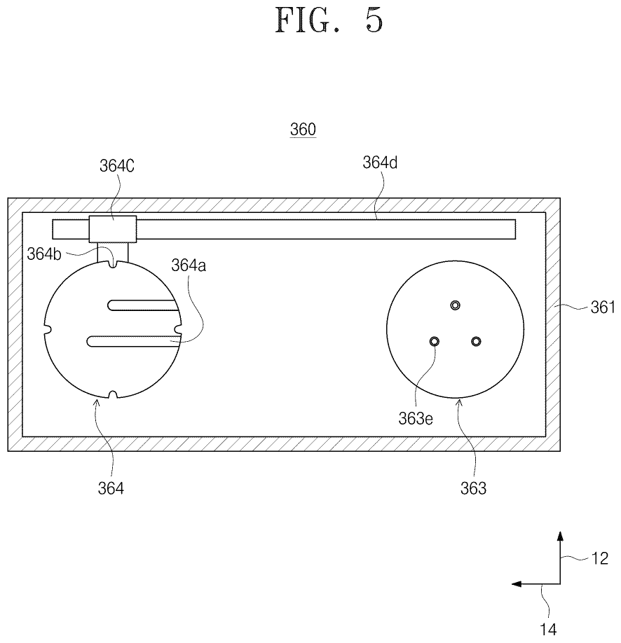

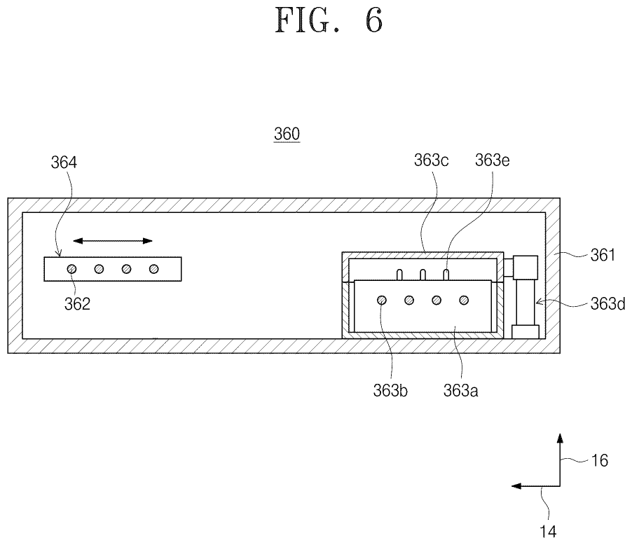

FIG. 5 is a top plan view schematically illustrating an example of the heat treating chamber of FIG. 3 or FIG. 4, and FIG. 6 is a front view of the heat treating chamber of FIG. 5.

Referring to FIGS. 5 and 6, the heat treating chamber 360 includes a housing 361, a heating unit 363, and a transfer plate 364.

The housing 361 is provided in a generally rectangular parallelepiped shape. An entrance opening (not illustrated) through which the substrate W enters and exits is formed on a sidewall of the housing 361. The entrance opening may remain open. Optionally, a door (not illustrated) may be provided to open and close the entrance opening. The heating unit 363 and the transfer plate 364 are provided within the housing 361.

The heating unit 363 includes a heating plate 363a, a cover 363c, and a heater 363b. When viewed from above, the heating plate 363a has a generally circular shape. The heating plate 363a has a larger diameter than the substrate W. The heater 363b is installed on the heating plate 363a. The heater 363b may be provided as a heating wire or a heating pattern that generates heat by supplying power. A lift pin 363e is provided at the heating plate 363a. The lift pin 363e is provided to be movable in the vertical direction along the third direction 16. The lift pin 363e receives the substrate W from the transfer robot 352 and puts the substrate W down on the heating plate 363a or lifts the substrate W up from the heating plate 363a to hand over the substrate to the transfer robot 352. According to an example, three lift pins 363e may be provided. The cover 363c has an inner space with an open lower portion. The cover 363c is positioned above the heating plate 363a and is moved in the vertical direction by a driver 363d. A space formed by the cover 363c and the heating plate 363a by moving the cover 363c is provided as a heating space for heating the substrate W.

The transfer plate 364 is generally provided with a disk shape and has a diameter corresponding to that of the substrate W. A notch 364b is formed at an edge of the transfer plate 364. The notch 364b may have a shape corresponding to that of the protrusion 352b formed in the hand of the transfer robot 352 described above. Also, the notches 364b are provided by the number corresponding to that of the protrusions 352b formed in the hand, and are formed at positions corresponding to the protrusions 352b. When the upper and lower positions of the hand and the transfer plate 364 are changed at the position where the hand and the transfer plate 364 are aligned in the vertical direction, the substrate W is transferred between the hand 354 and the transfer plate 364. The transfer plate 364 is mounted on the guide rail 364d and may be moved along the guide rail 364d by the driver 364c.

A plurality of slit-shaped guide grooves 364a is provided in the transfer plate 364. The guide groove 364a extends from the distal end of the transfer plate 364 to the inside of the transfer plate 364. The guide groove 364a is provided so that a longitudinal direction thereof is the second direction 14, and the guide grooves 364a are spaced apart from each other along the first direction 12. The guide groove 364a prevents the transfer plate 364 and the lift pin 363e from interfering with each other when the substrate W is taken over between the transfer plate 364 and the heating unit 363.

The transfer plate 364 is made of a material having high thermal conductivity. According to an example, the transfer plate 364 may be made of a metal material.

A cooling flow path 362 is formed in the transfer plate 364. The cooling water is supplied to the cooling flow path 362. The substrate W on which the heating has been completed in the heating unit 363 may be cooled in the middle of being transferred by the transfer plate 364. In addition, while the transfer plate 364 is stopped for the hand-over of the substrate W by the transfer robot 600, the substrate W may be cooled on the transfer plate 364.

Optionally, a cooling unit may be additionally provided in the housing 361. In this case, the cooling unit may be disposed side by side the heating unit 363. The cooling unit may be provided as a cooling plate having a passage through which cooling water flows. The substrate of which heating in the heating unit has been completed may be transferred to the cooling unit to be cooled.

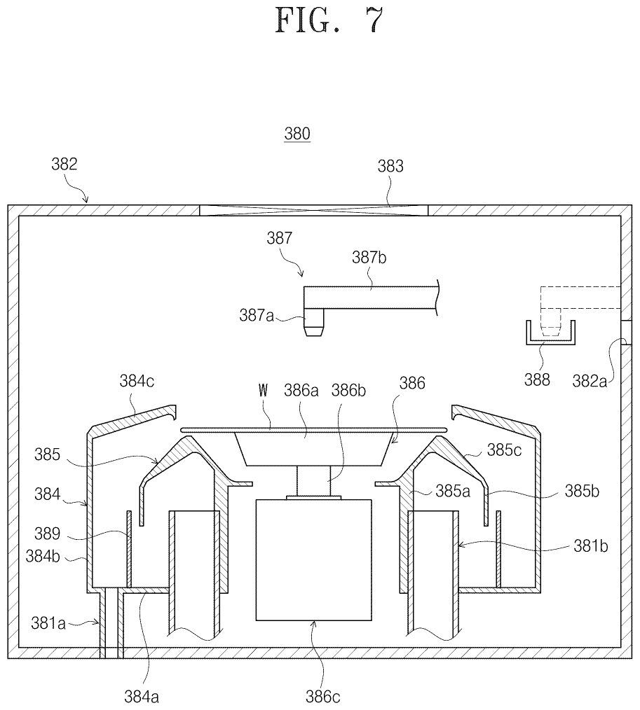

FIG. 7 is a front view schematically illustrating the liquid treating chamber of FIG. 3 or FIG. 4.

Referring to FIG. 7, the liquid treating chamber 380 includes a housing 382, a outer cup 384, a support unit 386, and a liquid supply unit 387.

The housing 382 is provided in a rectangular cylindrical shape having an inner space. An opening 382a is formed in one side of the housing 382. The opening 382a functions as a passage through which the substrate W enters and exits. A door (not illustrated) is installed in the opening 382a, and the door opens and closes the opening.

The outer cup 384 is provided in the inner space of the housing 382. The outer cup 384 has a treatment space with an open top.

The support unit 386 supports the substrate W in the treatment space of the outer cup 384. The support unit 386 includes a support plate 386a, a rotary shaft 386b, and a driver 386c. The support plate 386a has a circular upper surface. The support plate 386a has a smaller diameter than the substrate W. The support plate 386a is provided to support the substrate W by vacuum pressure. The rotary shaft 386b is coupled to the center of the bottom surface of the support plate 386a, and the rotary shaft 386b is provided with the driver 386c that provides the rotary shaft 386b with rotating force. The driver 386c may be a motor. Also, a lifting driver (not illustrated) for adjusting a relative height of the support plate 386a and the outer cup 384 may be provided.

The liquid supply unit 387 supplies a treatment liquid onto the substrate W. When the liquid treating chamber 380 is provided to the coating block 300a, the treatment liquid may be a liquid for forming a photoresist film, an antireflection film, or a protective film. When the liquid treating chamber 380 is provided to the developing block 300b, the treatment liquid may be a developer. The liquid supply unit 387 includes a nozzle 387a, a nozzle support 387b, and a liquid supply source (not illustrated). The nozzle 387a discharges the treatment liquid to the substrate W. The nozzle 387a is supported by the nozzle support 387b. The nozzle support 387b moves the nozzle 387a between a process position and a standby position. In the process position, the nozzle 387a supplies the treatment liquid to the substrate W placed on the support plate 386a, and the nozzle 387a, which has completed supplying the treatment liquid, waits in the standby position. In the standby position, the nozzle 387a stands by at a home port 388, and the home port 388 is located outside the outer cup 384 within the housing 382.

A fan filter unit 383 for supplying descending airflow to the inner space is disposed on the upper wall of the housing 382. The fan filter unit 383 includes a fan for introducing outside air into the inner space and a filter for filtering the outside air.

The outer cup 384 has a bottom wall 384a, a sidewall 384b, and an upper wall 384c. The inside of the outer cup 384 is provided as the aforementioned inner space. The inner space includes an upper treatment space and a lower exhaust space.

The bottom wall 384a is provided in a circular shape and has an opening in the center thereof. The sidewall 384b extends upwardly from the outer end of the bottom wall 384a. The sidewall 384b is provided in a ring shape and is provided perpendicular to the bottom wall 384a. For example, the sidewall 384b extends to the same height as the upper surface of the support plate 386a or extends to a height slightly lower than the upper surface of the support plate 386a. The upper wall 384c has a ring shape and an opening in the center thereof. The upper wall 384c is provided to be inclined upwardly from the upper end of the sidewall 384b toward the central axis of the outer cup 384.

The guide cup 385 is located inside the outer cup 384. The guide cup 385 has an inner wall 385a, an outer wall 385b, and an upper wall 385c. The inner wall 385a has a through hole penetrating in the vertical direction. The inner wall 385a is disposed to surround a driver 386c. The inner wall 385a minimizes the exposure of the driver 386c to the airflow 84 in the treatment space. A rotary shaft 386b or/and the driver 386c of the support unit 386 extend in the vertical direction through the through hole. The outer wall 385b is disposed to be spaced apart from the inner wall 385a and to surround the inner wall 385a. The outer wall 385b is positioned to be spaced apart from the sidewall 384b of the outer cup 384. The inner wall 385a is disposed to be spaced apart upwardly from the bottom wall 384a of the outer cup 384. The upper wall 385c connects the upper end of the outer wall 385b and the upper end of the inner wall 385a. The upper wall 385c has a ring shape and is disposed to surround the support plate 386a. According to an example, the upper wall 385c has a shape convex upwardly.

In the treatment space, a space below the support plate 386a may be provided as an exhaust space. According to an example, the exhaust space may be defined by the guide cup 385. A space surrounded by or below the outer wall 385b, the upper wall 385c, and the inner wall 385a of the guide cup 385 may be provided as an exhaust space.

The outer cup 384 may also be provided with a gas-liquid separating plate 389. The gas-liquid separating plate 389 may extend upwardly from the bottom wall 384a of the outer cup 384. The gas-liquid separating plate 389 may be provided in a ring shape. When viewed from above, the gas-liquid separating plate 389 may be positioned between the sidewall 384b of the outer cup 384 and the outer wall 385b of the guide cup 385. The upper end of the gas-liquid separating plate 389 may be positioned lower than the lower end of the outer wall 385b of the guide cup 385.

A discharge pipe 381a and an exhaust pipe 381b for discharging the treatment liquid are connected to the bottom wall 384a of the outer cup 384. The discharge pipe 381a may be connected to the outer cup 384 from the outside of the gas-liquid separating plate 389. The exhaust pipe 381b may be connected to the outer cup 384 from the inside of the gas-liquid separating plate 389.

The interface module 500 connects the treating module 300 to an external exposure device 700. The interface module 500 includes an interface frame 501, a buffer unit 510, a cooling unit 520, a transfer mechanism 530, an interface robot 540, and an additional process chamber 560.

A fan filter unit that forms a descending airflow therein may be provided at an upper end of the interface frame 501. The buffer unit 510, the cooling unit 520, the transfer mechanism 530, the interface robot 540, and the additional process chamber 560 are disposed within the interface frame 501.

Structures and disposition of the buffer unit 510 and the cooling unit 520 may be provided to be the same as or similar to those of the buffer unit 310 and the cooling unit 320 provided in the treating module 300. The buffer unit 510 and the cooling unit 520 are disposed adjacent to an end portion of the transfer chamber 350. The substrate W transferred between the treating module 300, the cooling unit 520, the additional process chamber 560, and the exposure device 700 may remain temporarily in the buffer unit 510. The cooling unit 520 may be provided only at a height corresponding to the coating block 300a between the coating block 300a and the developing block 300b.

The transfer mechanism 530 may transfer the substrate W between the buffer units 510. In addition, the transfer mechanism 530 may transfer the substrate W between the buffer unit 510 and the cooling unit 520. The transfer mechanism 530 may be provided in the same or similar structure as or to the transfer mechanism 330 of the treating module 300. Another transfer mechanism 531 may be further provided in a region opposite to the region in which the transfer mechanism 530 is provided with respect to the buffer unit 510.

The interface robot 540 is disposed between the buffer unit 510 and the exposure device 700. The interface unit 540 is provided to transfer the substrate W between the buffer unit 510, the cooling unit 520, the additional process chamber 560, and the exposure device 700. The interface robot 540 has a hand 542 on which the substrate W is placed, and the hand 542 may be provided to be capable of moving forward and backward, rotating about an axis parallel to the third direction 16, and moving along the third direction 16.

The additional process chamber 560 may perform a predetermined additional process before the substrate W on which the process has been completed in the coating block 300a is loaded into the exposure device 700. Optionally, the additional process chamber 560 may perform a predetermined additional process before the substrate W on which the process has been completed in the exposure device 700 is loaded into the developing block 300b. According to an example, the additional process may be an edge exposure process for exposing an edge region of the substrate W, an upper surface cleaning process for cleaning the upper surface of the substrate W, a lower surface cleaning process for cleaning the lower surface of the substrate W, or an inspection process of performing a predetermined inspection on the substrate W. A plurality of additional process chambers 560 may be provided, and they may be provided to be stacked on each other.

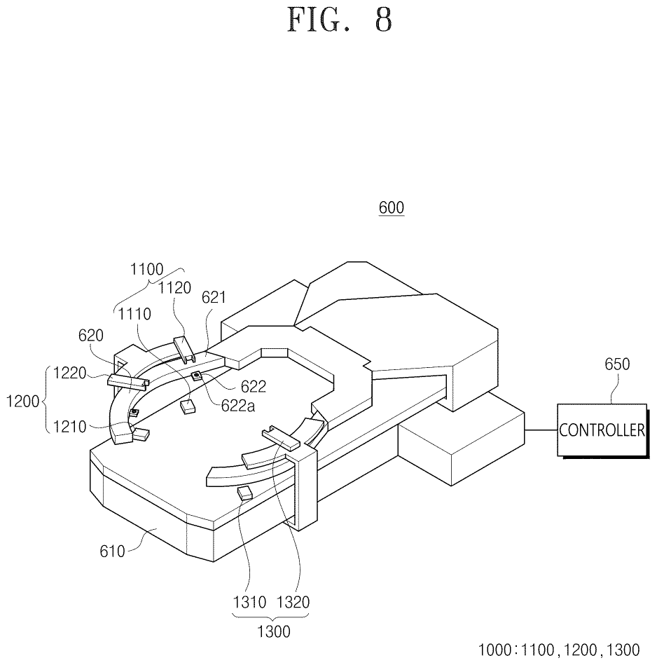

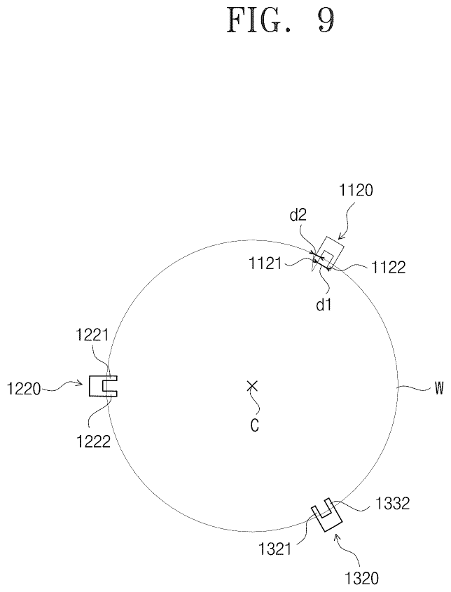

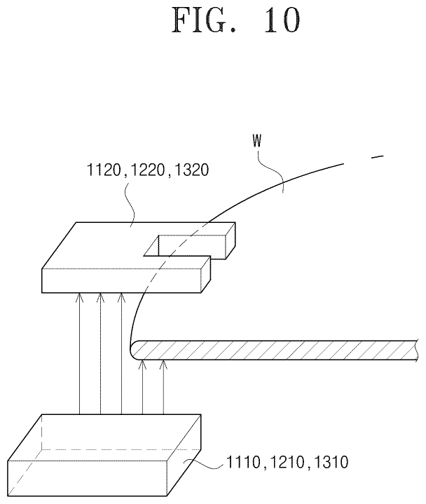

FIG. 8 is a perspective view schematically illustrating the transfer robot of FIG. 3. FIGS. 9 to 10 are diagrams for describing a light receiving unit according to the exemplary embodiment of the present invention.

Referring to FIG. 8, the transfer robot 600 includes a base 610, a hand 620, a position detector 1000, and a controller 650.

The base 610 is provided under the transfer robot 600. The base 610 supports the hand 620. Meanwhile, although only one hand 620 is illustrated in the drawing, a plurality of hands 620 may be provided. The base 610 may be provided to be movable on the guide rail 356. For example, the base 610 may be provided in a block shape having a set volume.

The hand 620 is mounted on the base 610. A substrate may be placed on the hand 620. The hand 620 may be retractable with respect to the base 610. The hand 620 supports the substrate. The hand 620 includes a body 621 and an adsorption part 622 formed on the body 621. The adsorption part 622 is formed with four protrusions 622a and supports the substrate in a manner in which the four protrusions 622a vacuum-adsorbs the substrate W.

When the substrate W is placed on the hand 620, the position detector 1000 detects the position of the substrate W placed on the hand 620.

The position detector 1000 includes a first sensor unit 1100, a second sensor unit 1200, and a third sensor unit 1300. Although it is illustrated that the position detector 1000 includes three sensor units 1100 to 1300, this is illustrative and the present invention is not limited thereto.

The first sensor unit 1100, the second sensor unit 1200, and the third sensor unit 1300 are included. The first sensor unit 1100, the second sensor unit 1200, and the third sensor unit 1300 are provided at positions corresponding to the three peripheral portions of the substrate W, respectively.

The first sensor unit 1100, the second sensor unit 1200, and the third sensor unit 1300 are configured identically, and the present invention will be described based on the first sensor unit 1100.

The first sensor unit 1100 includes a light emitting unit 1110 and a light receiving unit 1120. The light emitting unit 1110 is provided at a position corresponding to an outer edge of the substrate W.

The light emitting unit 1110 may be installed on a lower portion of the base 610. Alternatively, the light emitting unit 1110 may be installed above the hand 620. The light emitting unit 1100 may be provided in a bar shape. A size of the light emitting unit 1100 is equal to or larger than a size of the light receiving unit 1120. The light emitting unit 1110 emits light. For example, the light emitting unit 1000 may be an LED light source and may emit LED light. In this case, the light emitting unit 1100 may emit LED light having a short wavelength. Alternatively, the light emitting unit 1110 may be a laser light source and may provide laser light as light.

The light receiving unit 1120 is provided at a position corresponding to the outer edge of the substrate W. The light receiving unit 1120 is installed to face the light emitting unit 1110 in the vertical direction.

Referring to FIG. 9, the light receiving unit 1120 includes a first light receiving member 1121 and a second light receiving member 1122 as two light receiving members. Although it is illustrated that the light receiving unit 1120 includes two light receiving members 1121 and 1122, this is illustrative and may include a larger number of light receiving members.

The first light receiving member 1121 and the second light-receiving member 1122 may be light-receiving sensors. The light receiving sensor may be a Charge-Coupled Device (CCD). The first light receiving member 1121 and the second light receiving member 1122 may be provided in a bar shape. The first light receiving member 1121 and the second light receiving member 1122 are disposed along the circumferential direction with respect to the center of the substrate W. The distance d1 between the first light receiving member 1121 and the second light receiving member 1122 is greater than the width d2 of the notch N formed in the substrate W. Here, the width of the notch N is the width of the upper end of the notch N.

Referring to FIG. 10, the first light receiving member 1121 and the second light receiving member 1122 receive the light emitted by the light emitting unit 1110. The first light receiving member 1121 and the second light receiving member 1122 receive the light excluding the light covered by the substrate W among the light emitted by the light emitting unit 1110. The light emitted by the light emitting unit 1110 is incident on the first light receiving member 1121 and the second light receiving member 1122 in the vertical direction. The first light receiving member 1121 and the second light receiving member 1122 generate data on the received light. The data on the light may include information on the amount of light sensed by the first light receiving member 1121 and the second light receiving member 1122. The information on the amount of light may be information on the area of the light sensed by the first light receiving member 1121 and the second light receiving member 1122. The first light receiving member 1121 and the second light receiving member 1122 transmit the data on the light to the controller 650.

The controller 650 controls the hand 620 and the position detector 1000 based on data on light. The controller 650 receives data on light from the position detector 1000. The controller 650 may obtain information on the amount of light received by each of the light receiving members 1121, 1122, 1221, 1222 1231, and 1232 included in the plurality of sensor units 1100, 1200, and 1300 based on the data on the light. The controller 650 may determine a portion of the peripheral portion of the substrate W, in which the notch N is formed, through the obtained information.

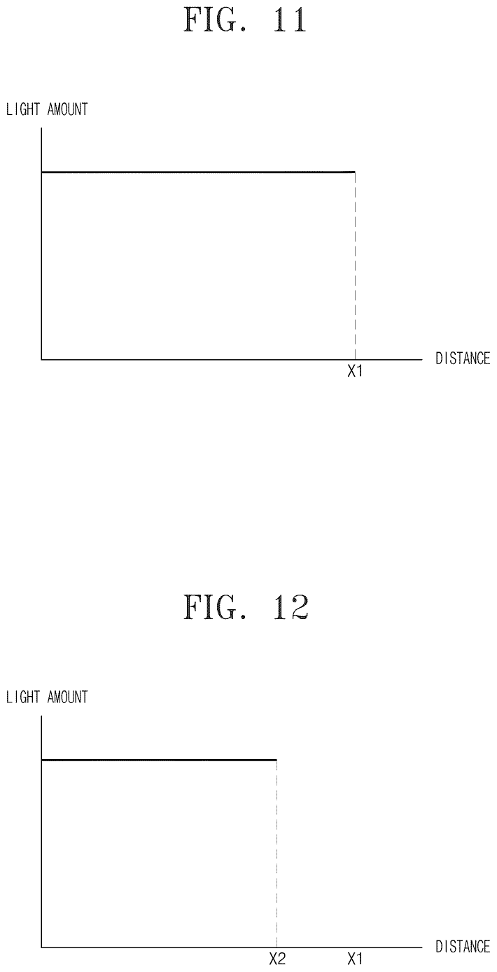

FIGS. 11 to 12 are conceptual diagrams illustrating a notch determining method according to an exemplary embodiment of the present invention.

FIG. 11 is a graph illustrating the amount of light received by the first light receiving member 1221 from the light emitting unit 1110 when the light receiving members 1121, 1122, 1221, 1222 1231, and 1232 are positioned as illustrated in FIG. 9, and FIG. 12 is a graph illustrating the amount of light received by each of the light receiving members 1122, 1221, 1222 1231, and 1232, except for the first light receiving member 1221, from the corresponding light emitting units 1110, 1120, and 1233.

Referring to FIGS. 11 to 12, the first light receiving member 1221 receives light up to a first distance x1, and the remaining light receiving members 112, 1221, 1222 1231, and 1232 receive light up to a second distance x2. That is, since the notch N is formed in the region where the first light receiving member 1221 is provided, the amount of light received by the first light receiving member 1221 is equal to or greater than the amount of light received by the other light receiving members 1122, 1221, 1222 1231, and 1232 by a preset value or more. In this case, the controller 650 may determine the portion in which the notch N is formed in the peripheral portion of the substrate W on which the first light receiving member 1221 is provided.

As the distance d1 between the first light receiving members 112, 1221, and 1321 and the second light-receiving members 112, 1222, and 1322 adjacent thereto is formed to be greater than the width d2 of the notch N formed in the substrate W, when any one light receiving member 1121 of the plurality of light-receiving members 1121, 1122, 1221, 1222 1231, and 1232 is provided in the region where the notch N is formed, the remaining light receiving members 112, 1221, 1222 1231, and 1232 are provided in the region where the notch is not formed, and the notch N may be easily detected.

Referring back to FIG. 8, the controller 650 may calculate the center point of the substrate W based on information on the amount of light received by each of the light receiving members 1121, 1122, 1221, 1222, 1231, and 1232. In this case, the controller 650 may calculate the center point of the substrate W in consideration of the detected notch N.

The controller 650 may compare the calculated center point of the substrate with a preset value to determine the degree of deviation of the substrate on the hand. The controller 650 may align the position of the substrate W based on the degree of deviation. The controller 650 may align the position of the substrate W by correcting the transfer position of the hand 620 on which the substrate W is placed.

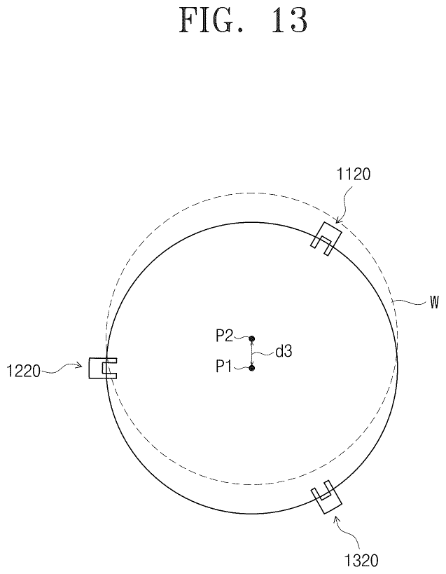

FIG. 13 is a conceptual diagram for describing a substrate position aligning method according to the exemplary embodiment of the present invention.

Referring to FIG. 13, the controller 650 may calculate P1 as the center point of the substrate W. The controller 650 may compare the calculated center point P1 of the substrate and a preset value P2, and determine that the substrate W is shifted by d3 on the hand 620. The controller 650 may align the position of the substrate W by correcting the transfer position of the hand 620 at which the substrate W is placed based on d3.

It should be understood that exemplary embodiments are disclosed herein and other modifications may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present disclosure, and all such modifications that would be obvious to one of ordinary skill in the art are intended to be included within the scope of the accompanying claims.

What is claimed is:

1. An apparatus for transferring a substrate, the apparatus comprising:
a base;
a hand mounted on the base to support the substrate; and
a position detector for detecting a position of the substrate supported by the hand,
wherein the position detector includes:
at least one sensor unit provided at each position corresponding to at least one peripheral portion of the substrate to detect the at least one peripheral portion of the substrate,
the at least one sensor unit includes:
a light emitting unit installed on any one of the base and the hand to emit light; and
a light receiving unit installed on the other of the base and the hand to receive the light emitted by the light emitting unit,
the light receiving unit includes a plurality of light receiving members, and
a gap between the plurality of light receiving members is greater than a width of a notch formed on the substrate.

2. The apparatus of claim 1, wherein the plurality of light receiving members is arranged in a circumferential direction based on a center of the substrate.

3. The apparatus of claim 2, wherein the width of the notch is a width of an upper end of the notch.

4. The apparatus of claim 1, wherein the plurality of light receiving members is provided as a plurality of light receiving sensors.

5. The apparatus of claim 4, wherein the light emitting unit is provided as a light source to emit the light to the plurality of light receiving sensors.

6. The apparatus of claim 4, wherein the at least one sensor unit is provided in plural to detect a plurality of peripheral portions of the substrate.

7. The apparatus of claim 6, further comprising:
a controller for controlling the hand and the position detector,
wherein the controller receives data on the light from the plurality of light receiving sensors included in the plurality of sensor units, respectively, and
obtains information on an amount of the light received by each of the plurality of light receiving sensors from the data on the light, and
when there is one light receiving sensor of which the amount of light received is equal to or greater than an amount of light received by other light receiving sensors by a preset value or more among the plurality of light receiving sensors, the controller determines that the notch is formed at a peripheral portion of the substrate corresponding to a position where the one light receiving sensor is provided.

8. The apparatus of claim 7, wherein the controller calculates a center point of the substrate based on information on the amount of light received by each of the plurality of light receiving sensors,
compares the center point of the substrate with a preset value to determine a degree of deviation of the substrate on the hand, and
aligns a position of the substrate based on the degree of deviation.

9. The apparatus of claim 1, wherein the light emitting unit is installed above the base, and
the light receiving unit is installed under the hand.

10. An apparatus for processing a substrate, the apparatus comprising:
an index module including a load port and an index robot; and
a treating module including a transfer chamber including a main transfer robot and a treating chamber placed on a side of the transfer chamber to process the substrate,
wherein the main transfer robot includes:
a base;
a hand mounted on the base to support the substrate; and
a position detector for detecting the position of the substrate supported by the hand,
the position detector includes a plurality of sensor units provided at positions corresponding to three peripheral portions to detect the three peripheral portions of the substrate,
each of the plurality of sensor units includes:
a light emitting unit installed above the base to emit light; and
a light receiving unit installed under the hand to receive the light emitted by the light emitting unit, and
the light receiving unit includes a plurality of light receiving sensors.

11. The apparatus of claim 10, wherein each of the plurality of light receiving sensors receives the light emitted by the light emitting unit to generate data on the light.

12. The apparatus of claim 11, wherein a gap between the plurality of light receiving sensors is greater than a width of a notch formed on the substrate.

13. The apparatus of claim 12, wherein the plurality of light receiving sensors is disposed along a circumferential direction with respect to a center of the substrate, and
the width of the notch is a width of an upper end of the notch.

14. The apparatus of claim 12, wherein the light emitting unit is provided as a light source to emit the light to each of the plurality of light receiving sensors.

15. The apparatus of claim 11, further comprising:
a controller for controlling the hand and the position detector,
wherein the controller receives data on the light from the plurality of light receiving sensors included in the plurality of sensor units, respectively, and
obtains information on an amount of light received by each of the plurality of light receiving sensors from the data on the light, and
when there is one light receiving sensor of which the amount of light received is equal to or greater than an amount of light received by other light receiving sensors by a preset value or more among the plurality of light receiving sensors, the controller determines that the notch is formed at a peripheral portion of the substrate corresponding to a position where the one light receiving sensor is provided.

16. The apparatus of claim 15, wherein the controller calculates a center point of the substrate based on information on the amount of light received by each of the plurality of light receiving sensors,
compares the center point of the substrate with a preset value to determine a degree of deviation of the substrate on the hand, and
aligns a position of the substrate based on the degree of deviation.

17. The apparatus of claim 10, wherein a size of the light emitting unit is equal to or greater than a size of the light receiving unit.

18. An apparatus for transferring a substrate, the apparatus comprising:
a base;
a hand mounted on the base to support a substrate;
a position detector for detecting a position of the substrate supported by the hand; and
a controller for controlling the hand and the position detector,
the position detector includes at least one sensor unit provided at each position corresponding to at least one peripheral portion of the substrate to detect the at least one peripheral portion of the substrate,
the at least one sensor unit includes:
a light emitting unit installed above the base to emit light; and
a light receiving unit installed under the hand to receive the light emitted by the light emitting unit, and
the light receiving unit includes a plurality of light receiving sensors, and
a gap between the plurality of light receiving sensors is greater than a width of a notch formed on the substrate.

19. The apparatus of claim 18, wherein the plurality of light receiving sensors is disposed along a circumferential direction with respect to a center of the substrate.

20. The apparatus of claim 18, wherein the width of the notch is a width of an upper end of the notch.
